(19) United States
(12) Patent Application Publication
(10) Pub. No.: US 2014/0266306 A1
(43) Pub. Date: Sep. 18, 2014

(54) HIGH SPEED DYNAMIC LATCH

(71) Applicant: John CULLINANE, Kilmallock (IE)

(72) Inventor: John CULLINANE, Kilmallock (IE)

(73) Assignee: Analog Devices Technology, Hamilton (BM)

(21) Appl. No.: 13/797,038

(22) Filed: Mar. 12, 2013

(51) Int. Cl. H03K 3/36

(52) U.S. Cl. CPC H03K 3/36
USPC 327/50; 327/200

(57) ABSTRACT

Embodiments of the present disclosure may provide a dynamic latch circuit with increased speed and that can perform comparisons on low input signals. The dynamic latch circuit may include a first input transistor receiving a first input signal and a second input transistor receiving a second input signal. A cross coupled inverters may be included to provide a first and second output signals based on the sampled input signals from the first and second input transistors. A reset circuit may be included to reset the first and second outputs to a reference voltage. The latch circuit may include an impedance controller coupled in parallel with the first and second input transistors.

### BACKGROUND

The subject matter of this application is directed to a dynamic latch, and more particularly to a high speed dynamic latch comparator.

Dynamic latches may be used to compare two input signals and output a signal based on the result of the comparison. The results may indicate which input signal has a higher value. Typically, a pair of back-to-back cross coupled inverters converts a voltage difference of the inputs into a digital full-scale output. Dynamic latches allow the comparison to be performed on low input signals and the comparison can be performed quickly. The quick decision speed of the dynamic latches has increased their use in analog-to-digital converters (ADCs).

Dynamic latches are designed for a particular application by optimizing one or more of the speed of the comparison, the number of circuit components, the amount of power consumption and accuracy of the comparison. The speed of the comparison is an important factor because many of the applications are requiring for the comparison to be performed at faster rates. The speed at which dynamic latches can compare consecutive input signals is limited by the characteristics of the circuit components and methods used to reset the dynamic latch after a comparison has been performed.

In some applications while the speed is improved the accuracy of the comparison is compromised. For example, some methods have improved the speed of the comparison by increasing the transconductance of the devices receiving the input signals. However, larger transconductance of the devices requires that more charge is injected onto the input nodes. The accuracy of the comparison may also suffer when the input signals are provided with low input signals. The accuracy of the comparison may be reduced due to, for example, mismatch in the circuit components.

Accordingly, there is a need in the art for high speed dynamic latches that will work with small input signals.

### BRIEF DESCRIPTION OF THE DRAWINGS

So that features of the present invention can be understood, a number of drawings are described below. It is to be noted, however, that the drawings illustrate only particular embodiments of the disclosure and are therefore not to be considered limiting of its scope, for the invention may encompass other equally effective embodiments.

FIG. 1 illustrates a latch circuit according to an embodiment of the present disclosure.

FIG. 2 illustrates a latch circuit according to another embodiment of the present disclosure.

FIG. 3 illustrates method for performing a comparison of input signals according to an embodiment of the present disclosure.

### DETAILED DESCRIPTION

Embodiments of the present disclosure may provide latch circuit with high speed and that can perform the comparison on low input signals. The dynamic latch circuit may include a first input transistor receiving a first input signal and a second input transistor receiving a second input signal. A cross coupled inverters may be included to provide a first and second output signals based on the sampled input signals from the first and second input transistors. A reset circuit may be included to reset the first and second outputs to a reference voltage. The latch circuit may include an impedance controller coupled in parallel with the first and second input transistors. The activation of the impedance controller may be delayed to allow the input signals to be provided to the first and second input transistors.

FIG. 1 illustrates a dynamic latch circuit 100 according to an embodiment of the present disclosure. The latch circuit 100 may include a pair of input transistors 132, 134, a pair of cross-coupled inverters INV1, INV2, a reset circuit RST and impedance control transistors 152, 154 provided in parallel with the input transistors 132, 134. The latch circuit 100 may provide an output signal at output terminals 122, 124 based on a comparison of input signals 112, 114 provided to the input transistors 132, 134, respectively. The dynamic latch circuit 100 performs the comparison by sampling the input signals 112, 114 onto the output terminals 122, 124 respectively, which are inputs to the inverters INV1, INV2. A sampled voltage at output 122 may drive inverter INV2 and a sampled voltage at output 124 may drive inverter INV1. When the inverters INV1, INV2 resolve, they may drive one of the output terminals (say, 122) to a first voltage supply VDD and the other output terminal 124 to a second voltage supply VSS.

In the embodiment illustrated in FIG. 1, the input transistors 132, 134 are illustrated as pull down transistors that are provided in a circuit path between the output terminals 122, 124 and a VSS supply voltage. Gate of the input transistors may be connected to a pair of inputs 112, 114, respectively. Thus, when activated, pull-down transistor 132 may pull down a voltage at output terminal 122 toward the second supply voltage VSS and pull-down transistor 134 may pull down a voltage at output terminal 124 toward the second supply voltage VSS. The input transistors 132, 134 may be formed of NMOS transistors in the illustrated embodiment.

The inverters INV1, INV2 each may be formed of a transistor pair 136/142 and 168/144. The transistors 136 and 138 may be coupled between the first supply voltage VDD and respective output terminals 122, 124. A gate of transistor 136 may be coupled to output terminal 124 and a gate of transistor 138 may be coupled to output terminal 122. The transistors 142, 144 may be coupled respectively between the output terminals 122, 124 and the input transistors 132, 134. A gate of the transistor 142 may be coupled to the output terminal 124 and a gate of the transistor 144 may be coupled to the output terminal 122. In the illustrated embodiment, the transistors 136, 138, when rendered conductive, may pull voltages at the output terminals 122, 124 respectively to VDD. The transistors 142, 144, when rendered conductive, may pull the voltages at the output terminals 122, 124 respectively to VSS (through other circuit components). In the illustrated embodiment, the transistors 136, 138, may be formed of PMOS transistors and the transistors 142,144 may be formed of NMOS transistors.

The reset circuit RST may include transistors 146, 148 and 150. Transistors 146, 148 may be coupled between the first supply voltage VDD and the output terminals 122, 124, respectively. The transistor 150 may be coupled to the input transistors 132, 134 at one node and to the second supply voltage VSS at a second node. Gates of the transistors 146, 148 and 150 may receive a common control signal CTRL1 to enable the dynamic latch. In the illustrated embodiment, the transistors 146, 148, may be formed of PMOS transistors and the transistor 150 may be formed of NMOS transistor.

The impedance control transistors 152, 154 may be provided in parallel with the input transistors 132, 134. In the embodiment illustrated in FIG. 1, first nodes of the impedance control transistors 152 154 are coupled respective to nodes A, B, where the input transistors 132, 134 are coupled to the inverters INV1 and INV2. Second nodes of the impedance control transistors 152, 154 may be coupled to VSS or to the transistor 150 (not shown). Gates of the impedance control transistors 152 and 154 may receive control signals CTRL2.

In operation, the latch circuit 100 may determine whether the input signal 112 provided to the gate of input transistor 132 is greater than the input signal provided to the gate of input transistor 134. The latch circuit 100 may include a reset phase and a comparison phase. During the reset phase control signal CTRL1 provides a low signal (e.g., signal having a first supply voltage value VSS) to the reset transistors 146, 148 and transistor 150 to reset the latch circuit 100. In response to the control signal CTRL1, the transistor 150 is “off” and reset transistors are “on”, to pull output terminals 122, 124 to the first supply voltage value VDD.

In the comparison phase, control signal CTRL1 having a high value (e.g., signal having a first supply voltage value VDD) is provided to the reset transistors 146, 148 and transistor 150 to turn “off” the reset transistors 146, 148 and to turn “on” the transistor 150. During the comparison phase, in response to the input signals at the gates of input transistors 132, 134, the input transistors 132,134 begin to pull down the voltage at output terminals 122, 124, respectively, to the second supply voltage value VSS (e.g., to ground). The rate at which each of the input transistors 132, 134 pulls down the voltage at and the output terminals 122, 124 is a function of the voltage level at the inputs 112, 114. Assuming that the transconductance (gm) of the input transistors 132, 134 is the same, a higher voltage at one of the inputs 112, 114 will cause a faster reduction in the voltage at the respective output terminal 122, 124.

Once a threshold is achieved at one of the output terminals 122, 124, the corresponding transistor 136 or 138 is activated to provide the first supply voltage value VDD at one of the output terminals 122, 124. Thus, if output terminal 122 reaches the threshold first, then transistor 138 and transistor 144 are activated to provide the first supply voltage value VDD at output terminal 124. In contrast, if output terminal 124 reaches the threshold first, then transistor 136 and transistor 142 are activated to provide supply voltage value VDD at output terminal 122. Eventually one of the output terminals 122, 124 will have a first supply voltage value VDD and the other node of nodes A and B will be pulled down to the second supply voltage value VSS (e.g., ground).

Thus, if the signal at input 112 has a lower value than the signal at input 114, after settling output terminal 124 will be pulled down to the second supply voltage VSS and output terminal 122 will return to the first supply voltage value VDD. In contrast, if the signal at input 114 has a lower value than the signal at input 112, after settling output terminal 122 will be pulled down to the second supply voltage VSS and output terminal 124 will return to the first supply voltage value VDD.

After the comparison phase, the reset phase may be repeated to bring both of the output terminals 122, 124 to the value of the first supply voltage value VDD.

As discussed above, the time that it takes to perform the comparison is a function of the input values 112, 114. In addition, the comparison time is related to the transconductance (gm) of the input transistors 132, 134 and the capacitance of the cross-coupled inverters INV1, INV2. The comparison time can be reduced by increasing the size of the input transistors 132, 134. However, larger input transistors 132, 134 increase the capacitive loading on previous stages, causing speed and accuracy issues.

Additional impedance devices may be included in parallel to input transistors 132, 134 and/or transistor 150 to increase the speed of the comparison after the initial values of the input signals are sampled to the output terminals 122, 124. The additional impedance devices allow for the speed of the comparison to be increased while maintaining smaller input transistors 132, 134. As shown in FIG. 1, the impedance control transistors 152, 154 may be included in the latch circuit 100 to improve the speed of the comparison. During the reset phase, the impedance control 152, 154 may be provided control signal CTRL2 to turn “off” the impedance control transistors 152, 154. During the comparison phase, control signal CTRL2 activates the impedance control transistors 152, 154 to increase the speed at which the output terminals 122,124 are resolved. The control signal CTRL2 to active the impedance control transistors 152, 154 may be delayed from the control signal CTRL1 used to activate transistor 150. The delay allows for the signals applied to the input transistors 132 and 134 to be sampled onto the output terminals 122, 124, respectively, before the impedance control 152, 154 are added to the circuit.

Adding the impedance control 152 and 154 reduces the comparison time by increasing the overall transconductance (gm) of the pull-down devices (e.g., transistors 132, 134, 150, 152, and 154). Impedance control transistors 152 and 154 may include a transconductance (gm) that is higher than the transconductance (gm) of one or more of the pull-down transistors 132, 134 and 150. Adding the impedance control transistors 152 and 154 also reduces the series resistance due to the transistors 132, 134, and 150.

In another embodiment (not shown in FIG. 1), the impedance control transistors 152 and 154 may be provided only in parallel to the input transistors 132, 134. Alternatively, one or more impedance control transistors (not shown in FIG. 1) could be provide only in parallel to the transistor 150. Other arrangements of impedance control transistors may be provided to increase the overall transconductance of the pull down devices after the impedance control transistors are activated.

The delay of the control signal CTRL2 may be set based on the desired accuracy of the dynamic latch circuit 100. For higher accuracy the delay could be increased, or in some cases switched off, to provide more time for the initial values of the input signals to be sampled to the output terminals 122, 124. In contrast, for lower accuracy the delay could be decreased to allow less time for the initial values of the input signals to be sampled to the output terminals 122, 124. The delay may be preset or changed dynamically based on the results of the comparison. Increasing the delay may increase the comparison time and decreasing the delay may decrease the comparison time.

The delay of the control signal CTRL2 may be preset based on the expected operating parameter or set based on average operating parameters of the dynamic latch circuit 100. The delay of the control signal CTRL2 may be based on the values of the input signals 112, 114. For example, the delay may be increased for input signals with lower values and decreased for input signals with higher values. The delay may be decreased for higher input signals with higher values because less time is needed to perform the comparison as compared to input values with lower values.

The delay may be a function of the difference between the input signals 112, 114. For example, large differences between the input signals 112, 114 may not need to be sampled onto the nodes A and B, respectively for a long time before activating impedance control transistors 152, 154.

The control signal CTRL1 and control signal CTRL2 may be provided by a clock signal. Control signal CTRL2 may be a variation of the control signal CTRL1 that is delayed by a predetermined amount. The devices receiving the control signals CTRL1 and CTRL2 may be edge triggered.

The first supply voltage VDD can be a positive supply voltage and the second supply voltage VSS can be a negative supply voltage, a lowest negative supply voltage or a ground.

In the embodiment illustrated in FIG. 1, the transistors 132, 134, 142, 144, 150, 152 and 154 are illustrated as pull-down NMOS transistors and transistors 136, 138, 146 and 148 are illustrated as pull-up PMOS transistors. The principles of the present invention, however, are not so limited. As will be understood by one skilled in the pertinent arts, the switch configurations described herein are not limited to the specific transistors depicted but are applicable to various transistor technologies including NMOS, PMOS, NDMOS and PDMOS transistors. In one embodiment the components shown in FIG. 1 may be flipped between the first supply voltage and the second supply voltage. Other arrangements of the pull-down devices and/or pull-up device may be used with these embodiments. In addition, other arrangements of the reset circuits may be used in accordance with these embodiments.

FIG. 2 illustrates a dynamic latch circuit 200 according to another embodiment of the present disclosure. The latch circuit 200 may include a pair of input transistors 232, 234, a pair of cross-coupled inverters INV1, INV2, a reset circuit RST (e.g., including transistors 246, 248 and 250) and impedance control transistors 252, 254 provided in parallel with the input transistors 232, 234. The latch circuit 200 may provide an output signal at output terminals 222, 224 based on a comparison of input signals 212, 214 provided to the input transistors 232, 234, respectively. The dynamic latch circuit 200 performs the comparison by sampling the input signals 212, 214 onto the output terminals 222, 224 respectively, which are inputs to the inverters INV1, INV2. A sampled voltage at output 222 may drive inverter INV2 and a sampled voltage at output 224 may drive inverter INV1. When the inverters INV1, INV2 resolve, they may drive one of the output terminals (say, 222) to a first voltage supply VSS and the other output terminal 224 to a second voltage supply VDD.

In the embodiment illustrated in FIG. 2, the input transistors 232, 234 are illustrated as pull up transistors that are provided in a circuit path between the output terminals 222, 224 and a VDD supply voltage. Gate of the input transistors 232, 234 may be connected to a pair of inputs 212, 214, respectively. Thus, when activated, pull-up transistor 232 may pull up a voltage at output terminal 222 toward the second supply voltage VDD and pull-up transistor 234 may pull up a voltage at output terminal 224 toward the second supply voltage VDD. The input transistors 232, 234 may be formed of PMOS transistors in the illustrated embodiment.

The inverters INV1, INV2 each may be formed of a transistor pair 236/242 and 238/244. The transistors 236 and 238 may be coupled between the first supply voltage VSS and respective output terminals 222, 224. A gate of transistor 236 may be coupled to output terminal 224 and a gate of transistor 238 may be coupled to output terminal 222. The transistors 242, 244 may be coupled respectively between the output terminals 222, 224 and the input transistors 232, 234. A gate of the transistor 242 may be coupled to the output terminal 224 and a gate of the transistor 244 may be coupled to the output terminal 222. In the illustrated embodiment, the transistors 236, 238, when rendered conductive, may pull voltages at the output terminals 222, 224 respectively to VSS. The transistors 242, 244, when rendered conductive, may pull the voltages at the output terminals 222, 224 respectively to VDD (through other circuit components). In the illustrated embodiment, the transistors 236, 238, may be formed of NMOS transistors and the transistors 242, 244 may be formed of PMOS transistors.

The reset circuit RST may include transistors 246, 248 and 250. Transistors 246, 248 may be coupled between the first supply voltage VSS and the output terminals 222, 224, respectively. The transistor 250 may be coupled to the input transistors 232, 234 at one node and to the second supply voltage VDD at a second node. Gates of the reset transistors 246, 248 and 250 may receive a common control signal CTRL1.

The impedance control transistors 252, 254 may be provided in parallel with the input transistors 232, 234. In the embodiment illustrated in FIG. 2, first nodes of the impedance control transistors 252, 254 are coupled respective to nodes A, B, where the input transistors 232, 234 are coupled to the inverters INV1 and INV2. Second nodes of the impedance control transistors 252, 254 may be coupled to VDD or to the transistor 250 (not shown). Gates of the impedance control transistors 252 and 254 may receive control signals CTRL2.

In operation, the dynamic latch circuit 200 may operate in a similar manner to the operation of the dynamic latch circuit 100 shown in FIG. 1.

FIG. 3 illustrates a method for performing a comparison of input signals according to an embodiment of the present disclosure. The method may be performed using the dynamic latch circuit shown in FIG. 1 or FIG. 2. The method may include supplying a first voltage to output nodes (box 210), supplying input signals to a first and second input devices, respectively (box 220), pulling down the voltages at the first and second output nodes based on the input signals (box 230), activating switches provided in parallel to the pull-down devices (box 240), resolving the values at the output nodes (box 250), and resetting the values at the output nodes (box 260).

Supplying a first voltage value to output nodes (box 210) may include resetting the dynamic latch circuit such that a first voltage value is provided at a first output node and at a second output node. The first voltage value may be provided to the first output from a first supply voltage via a first pull-up transistor that is activated via a control signal. The first voltage value may be provided to the second output from the first supply voltage via a second pull-up transistor that is activated via a control signal.

Supplying the first and second input signals to the first and second input device, respectively (box 220), may include providing the first input signal to a gate of the first input device and providing the second input signal to a gate of the second input device. The first input device may be coupled to the first output and the second input device may be coupled to the second output.

Once the first and second input signals are supplied to the respective input devices, the input devices may pull-down the voltages at the respective outputs (box 230). The rate at which each of the input devices pulls down the voltages at the output nodes is a function of the input signals values. Thus, a higher voltage at one of the inputs will cause the voltage at the respective output to be pulled down faster. Because the input devices are coupled to the second supply voltage, which may be ground, the input devices will pull-down the voltage at the respective outputs to the second supply voltage.

After the input signals are applied to the respective input devices, switches that are provided in parallel to the input devices may be activated (box 240). Because the input signals have the most effect on the result of the comparison at the beginning of the comparison, the switches that are provided in parallel to the input devices may be activated immediately after the input signals are sampled by the latch circuit onto the outputs. Activating the switches that are provided in parallel to the input devices increases the speed with which comparison can be performed.

Once a threshold is achieved at one of the outputs nodes, the corresponding cross coupled devices to the output nodes will be activated to provide the first supply voltage at one of the output nodes, while the other node is brought down to the second supply voltage value. These values (e.g., a first supply voltage value at one output and a second supply voltage at the other output) at the output nodes provide the comparison results of the input signals.

Once the comparison is complete the voltage values at the output nodes can be reset (box 260). Resetting the voltage values may include providing the first supply voltage via a first pull-up transistor to the first output node and providing the first supply voltage via the second pull-up transistor to the second output node. In addition, a pull-down device may be provided between first and second input devices. The additional pull-down device may be deactivated during the reset.

In the above description, for purposes of explanation, numerous specific details have been set forth in order to provide a thorough understanding of the inventive concepts. As part of this description, some structures and devices may have been shown in block diagram form in order to avoid obscuring the invention. Reference in the specification to “one embodiment” or “an embodiment” means that a particular feature, structure, or characteristic described in connection with the embodiment is included in at least one embodiment of the invention, and multiple references to “one embodiment” or “an embodiment” should not be understood as necessarily all referring to the same embodiment.

One or a plurality of the above illustrated operations may be implemented in a computer program that may be stored on a storage medium having instructions to program a system to perform the operations. The storage medium may include, but is not limited to, any type of disk including floppy disks, optical disks, compact disk read-only memories (CD-ROMs), compact disk rewritable (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, magnetic or optical cards, or any type of media suitable for storing electronic instructions. Other embodiments may be implemented as software modules executed by a programmable control device.

As used in any embodiment in the present disclosure, “circuitry” may comprise, for example, singly or in any combination, analog circuitry, digital circuitry, hardwired circuitry, programmable circuitry, state machine circuitry, and/or firmware that stores instructions executed by programmable circuitry. Also, in any embodiment herein, circuitry may be embodied as, and/or form part of, one or more integrated circuits.

Although the methods illustrated and described herein include series of steps, it will be appreciated that the different embodiments of the present disclosure are not limited by the illustrated ordering of steps, as some steps may occur in different orders, some concurrently with other steps apart from that shown and described herein. In addition, not all illustrated steps may be required to implement a methodology in accordance with the present invention. Moreover, it will be appreciated that the processes may be implemented in association with the apparatus and systems illustrated and described herein as well as in association with other systems not illustrated.

It will be appreciated that in the development of any actual implementation (as in any development project), numerous decisions must be made to achieve the developers' specific goals (e.g., compliance with system and business related constraints), and that these goals will vary from one implementation to another. It will also be appreciated that such development efforts might be complex and time consuming, but would nevertheless be a routine undertaking for those of ordinary skill in art having the benefit of this disclosure.

What is claimed is:

1. A dynamic latch circuit, comprising:
a first input transistors receiving a first input signal;
a second input transistor receiving a second input signal;
cross coupled inverters providing a first and second output signals based on the sampled input signals from the first and second input transistors;
a reset circuit to reset the first and second outputs to a reference voltage; and
an impedance controller coupled in parallel with the first and second input transistors.

2. The dynamic latch circuit of claim 1, wherein transconductance of the first and second input transistors is lower than the transconductance of the impedance controller.

3. The dynamic latch circuit of claim 1, wherein the impedance controller includes a first impedance controller transistor coupled in parallel to the first input transistor and a second impedance controller transistor coupled in parallel to the second input transistor.

4. The dynamic latch circuit of claim 3, wherein the first and second impedance controller transistors are activated in response to a control signal applied to gates of the first and second impedance controller transistors.

5. The dynamic latch circuit of claim 4, wherein the control signal is provided after the dynamic latch comparison is enabled.

6. The dynamic latch circuit of claim 5, wherein the control signal is delayed a predetermined time and the predetermined time is increased for higher accuracy comparison and decreased for lower accuracy comparison.

7. A dynamic latch circuit, comprising:
a first pull-down transistor coupled between a first output node and ground, a gate of the first pull-down transistor receiving a first input signal;
a second pull-down transistor coupled between a second output node and ground, a gate of the second pull-down transistor receiving a second input signal;
a third pull-down transistor coupled in parallel to the first pull-down transistor;
a fourth pull-down transistor coupled in parallel to the second pull-down transistor;
a first pull-up transistor coupled between a first supply voltage and the first output node, a gate of the first pull-down transistor is coupled to the second output node;
a second pull-up transistor coupled between the first supply voltage and the second output node, a gate of the first pull-down transistor is coupled to the first output node; and
a reset circuit to reset the values of the first and second output nodes to the value of the first supply voltage in response to a reset signal.

8. The dynamic latch circuit of claim 7, wherein transconductance of the first and second pull-down transistors is lower than the transconductance of the third and fourth pull-down transistors.

9. The dynamic latch circuit of claim 7, wherein the third and fourth pull-down transistors are activated in response to a control signal applied to gates of the third and fourth pull-down transistors.

10. The dynamic latch circuit of claim 9, wherein the control signal is provided after the dynamic latch comparison is enabled.

11. The dynamic latch circuit of claim 9, wherein the control signal is delayed a predetermined time after the dynamic latch comparison is enabled.

12. The dynamic latch circuit of claim 11, wherein the predetermined time is increased for higher accuracy comparison and the predetermined time is decreased for lower accuracy comparison.

13. The dynamic latch circuit of claim 11, wherein the predetermined time is increased for slower comparison and the delay is decreased for faster comparison.

14. The dynamic latch circuit of claim 7, wherein the reset circuit includes a fifth pull-down transistor coupled between the first and second pull-down transistors and ground, a gate of the fifth pull-down transistor receiving the reset signal.

15. The dynamic latch circuit of claim 7, further comprising:
a fifth pull-down transistor coupled between the first pull-down transistor and the first output node, a gate of the fifth pull-down transistor being coupled to the second output node; and
a sixth pull-down transistor coupled between the second pull-down transistor and the second output node, a gate of the sixth pull-down transistor being coupled to the first output node.

16. The dynamic latch circuit of claim 7, wherein the reset circuit includes:
a fifth pull-down transistor coupled between the first and second pull-down transistors and ground, a gate of the firth pull-down transistor receiving the reset signal;
a third pull-up transistor coupled in parallel to the first pull-up transistor, a gate of the third pull-up transistor receiving the reset signal; and
a fourth pull-up transistor coupled in parallel to the second pull-up transistor, a gate of the fourth pull-up transistor receiving the reset signal.

17. A method for comparing a first and a second input signal, comprising:
supplying a first voltage value to first and second outputs;
in response to the first input signal being applied to a first input device, pulling down the voltage at the first output via the first input device;
in response to the second input signal being applied to a second input device, pulling down the voltage at the first output via the second input device;
after applying the first input signal to the first input device, activating a first switching device provided in parallel to the first input device;
after applying the second input signal to the second input device, activating a second switching device provided in parallel to the second input device;
resolving one of the first and second outputs to the first voltage value and the other one of the first and second outputs to ground, based on a rate at which the voltages at the outputs are pulled down.

18. The method of claim 17, wherein activating the first and second switches increases the transconductance of the devices pulling down the voltage at the outputs.

19. The method of claim 17, wherein the first voltage value is provided to the output node coupled to the input receiving a lower input signal and ground is applied to the output node coupled to the input receiving a higher input signal.

20. The method of claim 17, wherein activating the first switching device and the second switching device is delayed a predetermined period of time after the first and second input signals are applied the first and second input devices.
